(19) United States
(12) Patent Application Publication
(10) Pub. No.: US 2017/0069809 A1
(43) Pub. Date: Mar. 9, 2017

(54) LIGHT-EMITTING DIODE PACKAGE

(71) Applicant: Lextar Electronics Corporation, Hsinchu (TW)

(72) Inventors: Jo-Shung Chen, New Taipei City (TW); Chih-Hao Lin, Taipei City (TW); Tzong-Liang Tsai, Taichung City (TW)

(21) Appl. No.: 15/227,067

(22) Filed: Aug. 3, 2016

(30) Foreign Application Priority Data
Sep. 7, 2015 (TW) 104129508

(51) Int. Cl. H01L 33/62; H01L 33/50; H01L 33/60

(52) U.S. Cl. CPC H01L 33/62; H01L 33/60; H01L 33/502; H01L 2933/0066; H01L 2933/0058

(57) ABSTRACT

A light-emitting diode package is provided. The light-emitting diode package includes a lead-frame, a reflective cup and a die. The lead-frame is made of a silver-free material. The reflective cup has the cavity. The die is disposed on the lead-frame in a face-down orientation, and is further electrically connected to the lead-frame and located within the cavity.

This application claims the benefit of Taiwan application Serial No. 104129508, filed Sep. 7, 2015, the disclosure of which is incorporated by reference herein in its entirety.

### TECHNICAL FIELD

The disclosure relates in general to a light-emitting diode package, and more particularly to a light-emitting diode package having silver-free lead-frame.

### BACKGROUND

Conventionally, the light-emitting die of the light-emitting diode package is disposed on the lead-frame. In order to increase the reflectivity, a silver layer is normally formed on the lead-frame. However, the silver layer easily vulcanizes with the sulfide of the package and generate black silver sulfide. This is also referred as “blackening phenomenon” which deteriorates the optical properties of the light-emitting diode package. For example, the reflectivity deteriorates.

Therefore, it has become a prominent task for the industries to provide a new light-emitting diode package to resolve the problem of blackening phenomenon.

### SUMMARY

The disclosure is directed to a light-emitting diode package capable of resolving the blackening phenomenon.

According to one embodiment, a light-emitting diode package is provided. The light-emitting diode package includes a lead-frame, a reflective cup and a die. The lead-frame is made of a silver-free material. The reflective cup has a cavity. The die is disposed on the lead-frame in a face-down orientation, and is further electrically connected to the lead-frame and located within the cavity.

According to another embodiment, a manufacturing method of light-emitting diode package is provided. The method includes following steps. A lead-frame made of a silver-free material is provided. A reflective cup is formed encapsulating the lead-frame, wherein the reflective cup a cavity. A die is disposed on the lead-frame in a face-down orientation and located within the cavity.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1A is a cross-sectional view of a light-emitting diode package according to an embodiment of the invention;

FIG. 1B is a top view of the light-emitting diode package of FIG. 1A; and

FIGS. 2A to 2F are manufacturing processes of the light-emitting diode package of FIG. 1.

### DETAILED DESCRIPTION

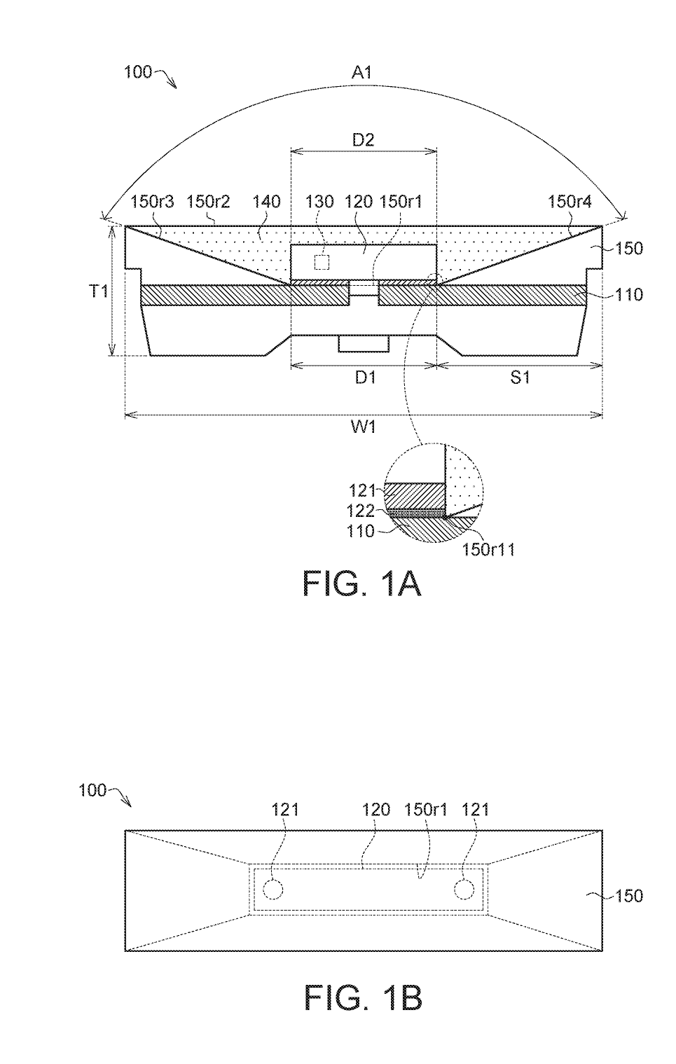

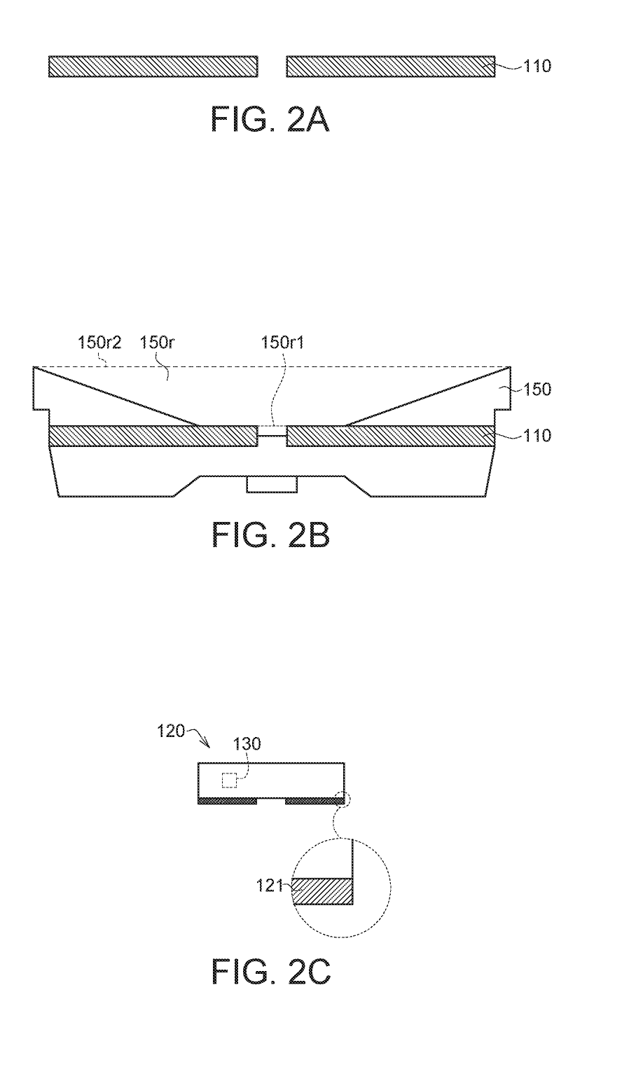

Refer to FIGS. 1A and 1B. FIG. 1A is a cross-sectional view of a light-emitting diode package 100 according to an embodiment of the invention. FIG. 1B is a top view of the light-emitting diode package 100 of FIG. 1A.

The light-emitting diode package 100 includes a lead-frame 110, a die 120, an electrostatic discharge element 130, a conversion layer 140 and a reflective cup 150.

The lead-frame 110 is made of a silver-free material and capable of resolving the blackening problem, hence avoiding the reflectivity of the light-emitting diode package 100 deteriorating, and making the National Television Standards Committee (NTSC) test of the light-emitting diode package 100 higher than 90%. In an embodiment, the lead-frame 110 can be formed of gold (Au), aluminum (Al), copper (Cu), nickel (Ni), tin (Sn), an alloy thereof, or other silver-free conductive materials.

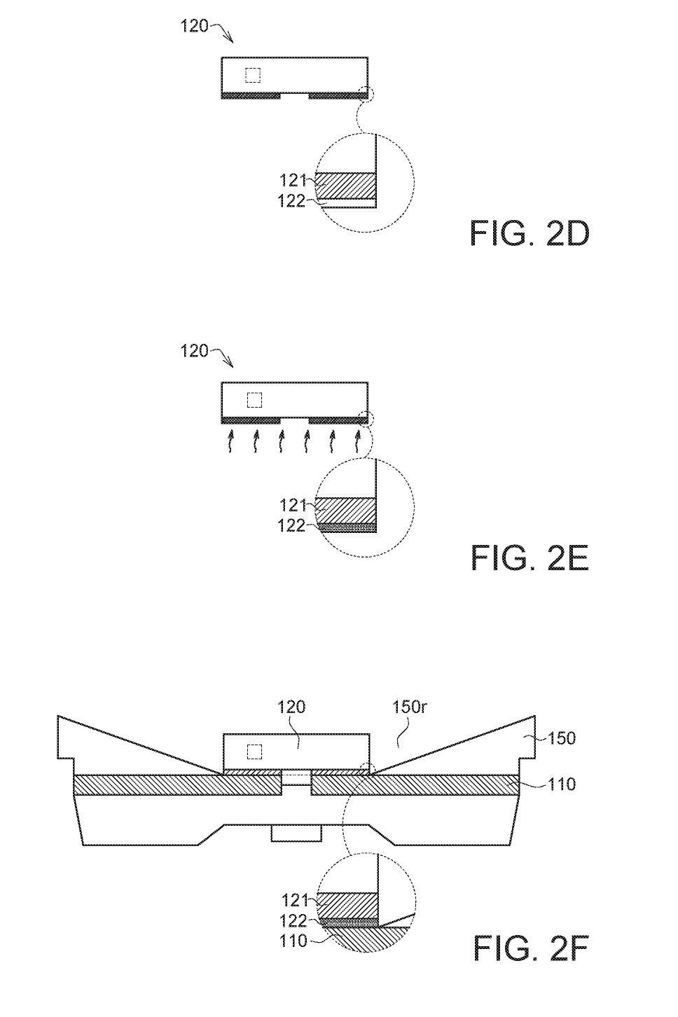

The die 120 can be realized by a light-emitting diode die. The die 120 is located within the cavity 150r of the reflective cup 150. The cavity 150r (illustrated in FIG. 2B) has a bottom opening 150r1 and a top opening 150ir2, wherein the area of the top opening 150r2 is larger than that of the bottom opening 150r1. The die 120 is disposed on the lead-frame 110 through the bottom opening 150r1.

The die 120 is disposed on the lead-frame 110 in a face-down orientation and is electrically connected to the lead-frame 110, such that the conventional solder wire region can be dispensed with. Thus, even when the inner diameter D1 of the bottom opening 150r1 is designed to be substantially equivalent to the outer diameter D2 of the die 120 (that is, the edge 150r11 of the bottom opening 150r1 can be close to the lateral surface of the die 120), the die 120 still can be disposed on the lead-frame 110 through the bottom opening 150r1. As indicated in FIG. 1B, since the conventional solder wire region is disposed with, the roof square of the die 120 is equivalent to or slightly smaller than that of the bottom opening 150r1.

Since the die 120 is disposed on the lead-frame 110 in a face-down orientation, the conventional solder wire can be dispensed with, and the thickness T1 of the reflective cup 150 (conventional solder wire) can be effectively reduced. In an embodiment, the thickness T1 of the reflective cup 150 is between 0.05 millimeters and 0.4 millimeters.

As indicated in FIG. 1A, the die 120 includes a pad 121 and a pre-plating layer 122. Before the die 120 is disposed on the lead-frame 110, the pre-plating layer 122 can be pre-plated on the pad 121. After the die 120 is disposed on the lead-frame 110, the pre-plating layer 122 is located between the pad 121 and the lead-frame 110, such that the die 120 can be more tightly disposed on the lead-frame 110 through the pre-plating layer 122. In an embodiment, the pre-plating layer 122 can be formed of gold (Au), silver (Ag), tin (Sn), nickel (Ni), bismuth (Bi), indium (In), copper (Cu) or an alloy thereof such as AuSn, AuSn SnCu or BiInSn.

In addition, the electrostatic discharge element 130 can divert the static electricity of the die 120 to the ground potential. In the present embodiment, the electrostatic discharge element 130 is embedded inside the die 120. That is, the electrostatic discharge element 130 and the die 120 can be integrated into one element, such that the electrostatic discharge element 130 will not occupy the space of the lead-frame 110, and the overall width W1 of the light-emitting diode package 100 can be reduced.

The wavelength conversion layer 140 is formed within the cavity 150r and encapsulates the die 120. In the present embodiment, since the roof 2( )square of the die 120 is slightly smaller than that of the bottom opening 150r1, the wavelength conversion layer 140 is further formed on part of the lead-frame 110. In another embodiment, if the roof square if the die 120 is equivalent to that of the bottom opening 150r1, the wavelength conversion layer 140 is not necessarily formed on the lead-frame 110. Since the lead-frame 110 is made of a silver-free material, the wavelength conversion layer 140 may have sulfur-containing fluorescent particles. In an embodiment, the wavelength conversion layer 140 can be made of a material such as sulfide, yttrium aluminum garnet (YAG), LuAG, silicate, nitride, oxynitride, fluoride, TAG, KSF, and KTF. The reflective cup 150 has a reflectivity higher than 95% to increase light extraction efficiency. In an embodiment, the reflective cup 150 can be formed of poly phthalic amide (PPA), polyamide (PA), polyethylene terephthalate (PTT), polyethylene terephthalate (PET), polyethylene terephthalate, 1,4 cyclohexane dimethanol ester (PCT), epoxy compound (EMC), silicone compound (SMC) or other resin/ceramic material with high reflectivity.

The cavity 150r of the reflective cup 150 has two opposite sidewalls 150r3 and 150r4, which form an angle A1. When the edge of the bottom opening 150r1 moves away from the die 120, the horizontal distance S1 between the edge of the opening 150r1 and the edge of the top opening 150r2 will be reduced. Under such circumstance, the angle A1 will be reduced and the light output angle will also be reduced. In the embodiments of the invention, when the edge of the bottom opening 150r1 move towards the die 120, the horizontal distance S1 between the edge of the bottom opening 150r1 and the edge of the top opening 150r2 will be increased. Under such circumstance, the angle A1 will be increased, and the light output angle will also be increased. In an embodiment, the angle A1 between the side walls 150r3 and 150r4 is between 150° and 180°, and such range effective increases the light output angle of the light-emitting diode package 100f.

FIGS. 2A to 2F are manufacturing processes of the light-emitting diode package of FIG. 1.

As indicated in FIG. 2A, a lead-frame 110 made of a silver-free material is provided.

As indicated in FIG. 2B, a reflective cup 150 can be formed by the packaging technology for encapsulating the lead-frame 110, wherein the reflective cup 150 has a cavity 150r.

As indicated in FIG. 2C, a die 120 is provided, wherein the die 120 includes at least a pad 121.

As indicated in FIG. 2D, a pre-plating layer 122 in a liquid state can be formed on the pad 121 by way of printing or coating.

As indicated in FIG. 2E, the pre-plating layer 122 formed on the pad 121 can be pre-heated at about 150° C. for about 15 minutes to reduce the liquidity of the pre-plating layer 122, For example, the pre-plating layer 122 can be heated to enter a colloidal state. Here, the pre-heating temperature and/or pre-heating time can be determined according to the properties of the pre-plating layer 122, and are not subject to the embodiments of the invention.

As indicated in FIG. 2F, the die 120 can be disposed on the lead-frame 110 in a face-down orientation, wherein the die 120 is located within the cavity 150r of the reflective cup 150. Since the liquidity of the pre-plating layer 122 is reduced, despite that the die 120 is disposed on the lead-frame 110 in a face-down orientation (the pre-plating layer 122 faces downwards), the pre-plating layer 122 will not flow easily. If the pre-plating layer 122 flows easily, the lead-frame 110 will be polluted and the two pads 121 will be short-circuited.

Then, the pre-plating layer 122 can be heated at about 200° C. for about 30 minutes to harden or cure the pre-plating layer 122, such that the pre-plating layer 122 can bond the pad 121 and the lead-frame 110 together tightly. Here, the hardening or curing temperature and/or the hardening or curing time can be determined according to the properties of the pre-plating layer 122, and are not subject to the embodiments of the invention. Thus, the formation of the light-emitting diode package 100 of FIG. 1A is completed.

It will be apparent to those skilled in the art that various modifications and variations can be made to the disclosed embodiments. It is intended that the specification and examples be considered as exemplary only, with a true scope of the disclosure being indicated by the following claims and their equivalents.

What is claimed is:

1. A light-emitting diode package, comprising:
a lead-frame made of a silver-free material;
a reflective cup having a cavity; and
a die disposed on the lead-frame in a face-down orientation, electrically connected to the lead-frame and located within the cavity.

2. The light-emitting diode package according to claim 1, wherein the cavity has a bottom opening through which the die is disposed on the lead-frame, and an inner diameter of the bottom opening is substantially equivalent to an outer diameter of the die.

3. The light-emitting diode package according to claim 1, further comprising:
a wavelength conversion layer formed within the cavity and encapsulating the die, wherein the wavelength conversion layer has sulfur-containing fluorescent particles.

4. The light-emitting diode package according to claim 1, wherein the reflective cup has a reflectivity higher than 95%.

5. The light-emitting diode package according to claim 1, wherein the die comprises a pad and a pre-plating layer pre-plated on the pad and located between the pad and the lead-frame.

6. The light-emitting diode package according to claim 1, wherein the cavity has two opposite sidewalls, and an included angle between the two sidewalls ranges between 150° and 180°.

7. The light-emitting diode package according to claim 1, wherein the reflective cup has a thickness ranging between 0.05 millimeters and 0.4 millimeters.

8. The light-emitting diode package according to claim 1, further comprising:
an electrostatic discharge element embedded inside the die.

9. A manufacturing method of light-emitting diode package, comprising:
providing a lead-frame made of a silver-free material;
forming a reflective cup encapsulating the lead-frame, wherein the reflective up has a cavity; and
disposing a die on the lead-frame in a face-down orientation, wherein the die is located within the cavity.

10. The manufacturing method according to claim 9, wherein prior to the step of disposing the die on the lead-frame, the manufacturing method further comprises:
providing the die comprising a pad;
forming a pre-plating layer on the pad;
pre-heating the pre-plating layer formed on the pad;
following the step of disposing the die on the lead-frame, the manufacturing method further comprises:
hardening the pre-plating layer.
